(19) United States
(12) Patent Application Publication
(10) Pub. No.: US 2025/0374436 A1
(43) Pub. Date: Dec. 4, 2025

(54) ELECTRONIC DEVICE

(71) Applicant: Advanced Semiconductor Engineering, Inc., Kaohsiung (TW)

(72) Inventors: Yu-Lun LU, Kaohsiung (TW); Yi-Jhan SHIH, Kaohsiung (TW)

(73) Assignee: Advanced Semiconductor Engineering, Inc., Kaohsiung (TW)

(21) Appl. No.: 18/679,316

(22) Filed: May 30, 2024

(51) Int. Cl. H05K 1/18; H05K 1/02; H05K 3/34

(52) U.S. Cl. CPC H05K 1/189; H05K 1/0283; H05K 1/181; H05K 3/3436; H05K 2201/10734; H05K 2201/10977

(57) ABSTRACT

The present disclosure provides an electronic device. The electronic device includes a carrier configured to be stretchable and a first electronic component disposed over the carrier. The electronic device also includes a structure at least partially disposed within the carrier and connected to the first electronic component. The structure is configured to reduce displacement between the carrier and the first electronic component.

### BACKGROUND

### 1. Technical Field

The present disclosure relates to an electronic device.

### 2. Description of the Related Art

A wearable device may include a flexible carrier, which may be bendable and stretchable so that the wearable device can adhere to and move with the user's body. Components or packages (such as System in Package (SiP)) may be integrated into the wearable device to perform functions, such as obtaining information or signals reflecting physical activity and/or health, capturing pictures, connecting to the Internet, and other tasks.

The components may be relatively more rigid than the flexible carrier. The interface between two different materials (or between high modulus and low modulus materials) might deteriorate (delaminate, crack, or break) when the wearable device is stretched or bent to conform to the user's body. Transmission problems may become severe, affecting detection quality and device reliability.

### SUMMARY

In some arrangements, an electronic device includes a carrier configured to be stretchable and a first electronic component disposed over the carrier. The electronic device also includes a structure at least partially disposed within the carrier and connected to the first electronic component. The structure is configured to reduce displacement between the carrier and the first electronic component.

In some arrangements, an electronic device includes a carrier configured to be stretchable and a first electronic component disposed over the carrier. The electronic device also includes a first structure vertically extending in the carrier and connected to the first electronic component. The first structure is configured to mitigate a stress from a strain of the carrier.

In some arrangements, an electronic device includes a carrier configured to be stretchable, and a first electronic component disposed over the carrier. The electronic device also includes a plurality of first structures disposed within the carrier and under the first electronic component. At least some of the plurality of first structures are configured to individually distribute a stress between the carrier and the first electronic component.

### BRIEF DESCRIPTION OF THE DRAWINGS

Aspects of some arrangements of the present disclosure are best understood from the following detailed description when read with the accompanying figures. It is noted that various structures may not be drawn to scale, and dimensions of the various structures may be arbitrarily increased or reduced for clarity of discussion.

FIG. 1A illustrates a cross-sectional view of an electronic device in accordance with some arrangements of the present disclosure.

FIG. 1B illustrates a cross-sectional view of an electronic device in accordance with some arrangements of the present disclosure.

FIG. 1C illustrates a cross-sectional view of an electronic device in accordance with some arrangements of the present disclosure.

FIG. 1D illustrates a top view and a cross-sectional view of an electronic device in accordance with some arrangements of the present disclosure.

FIG. 1E illustrates a conceptual view showing a state in which a user wears an electronic device in accordance with some arrangements of the present disclosure.

FIG. 1F illustrates a top view and a cross-sectional view of an electronic device in accordance with some arrangements of the present disclosure.

FIG. 2 illustrates a cross-sectional view of an electronic device in accordance with some arrangements of the present disclosure.

FIG. 3A illustrates a top view of an electronic device in accordance with some arrangements of the present disclosure.

FIG. 3B illustrates a top view of an electronic device in accordance with some arrangements of the present disclosure.

FIG. 3C illustrates a top view of an electronic device in accordance with some arrangements of the present disclosure.

FIG. 4A, FIG. 4B, FIG. 4C, FIG. 4D, FIG. 4E, and FIG. 4F illustrate cross-sectional views in one or more stages of a method of manufacturing an electronic device in accordance with an arrangement of the present disclosure.

### DETAILED DESCRIPTION

Common reference numerals are used throughout the drawings and the detailed description to indicate the same or similar components. Arrangements of the present disclosure will be readily understood from the following detailed description taken in conjunction with the accompanying drawings.

The following disclosure provides many different arrangements, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include arrangements in which the first and second features are formed or disposed in direct contact, and may also include arrangements in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various arrangements and/or configurations discussed.

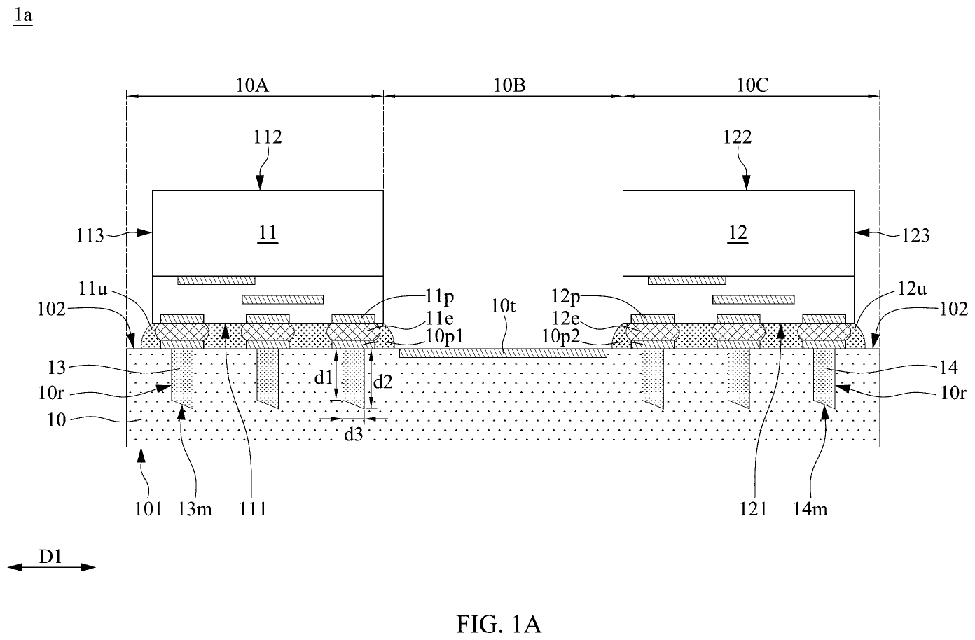

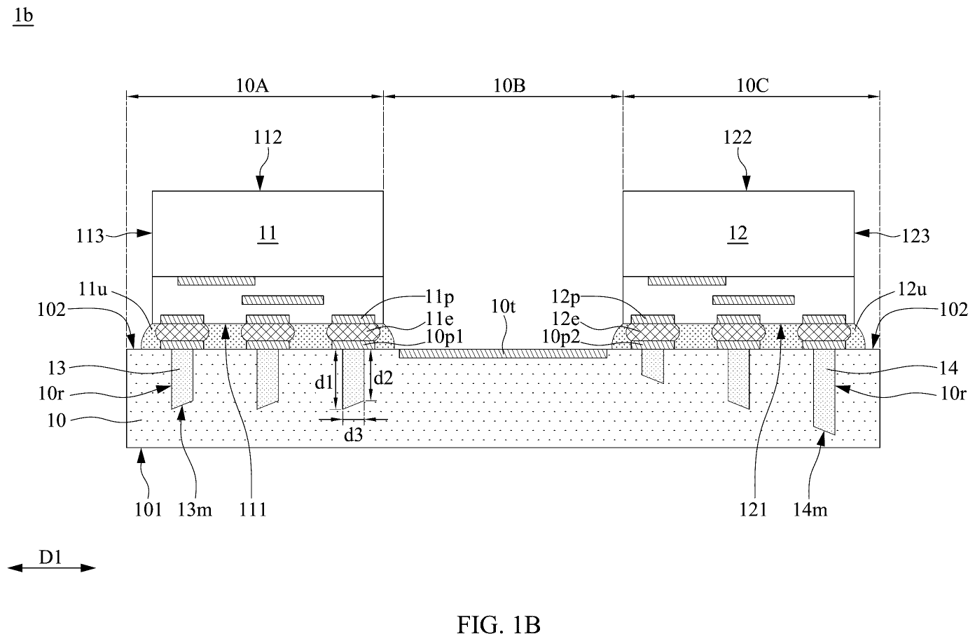

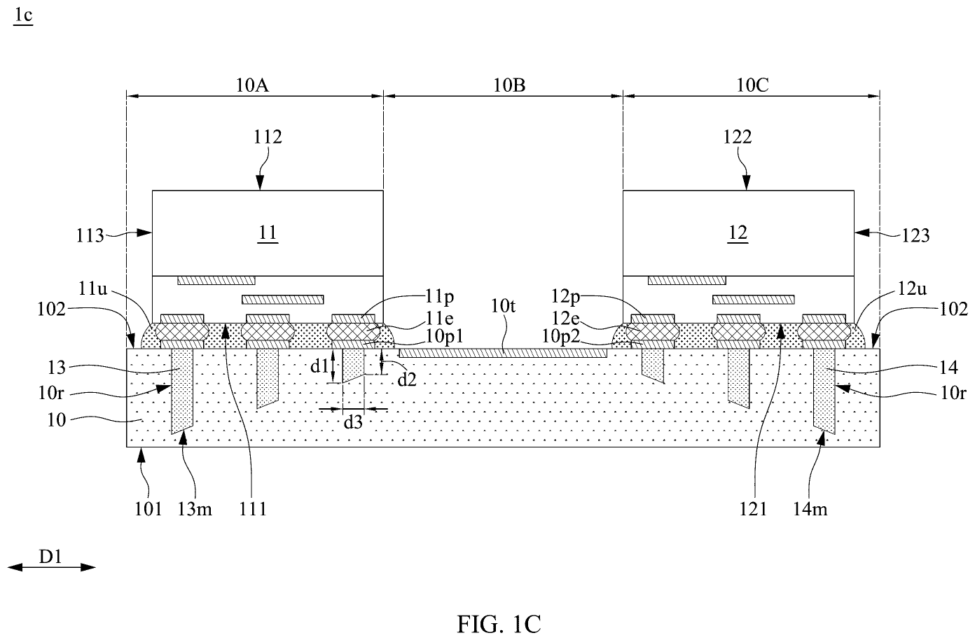

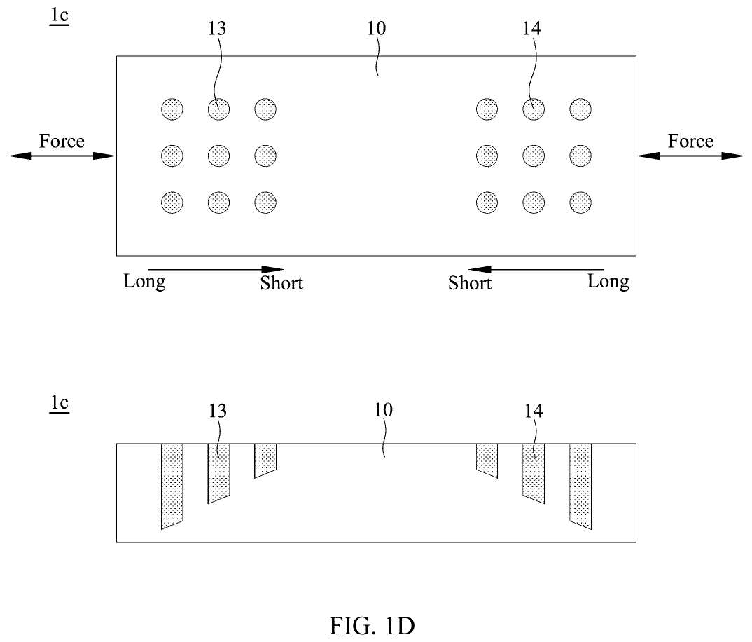

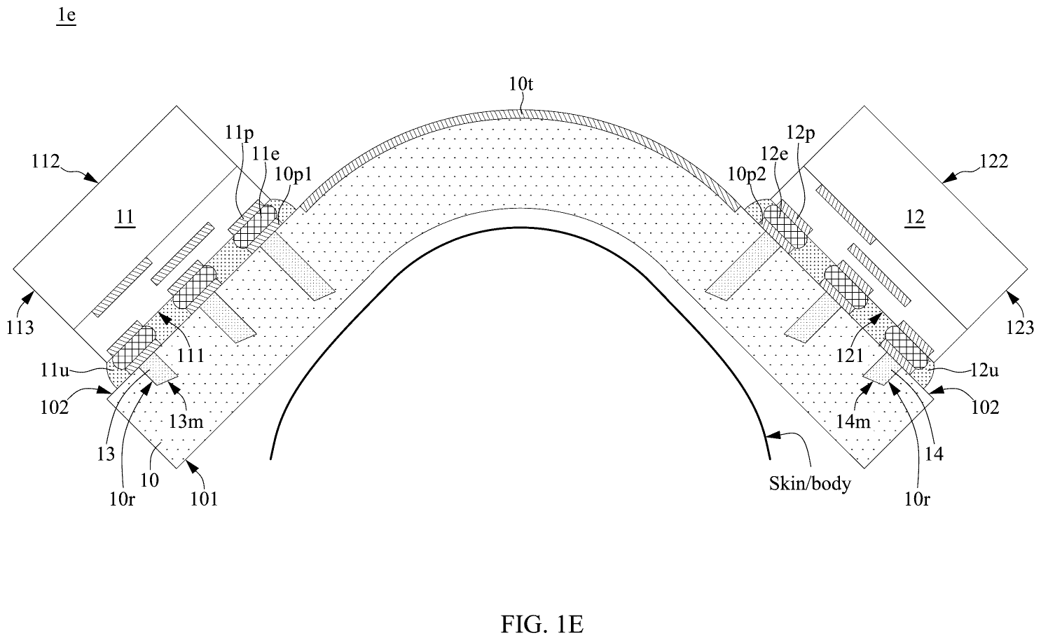

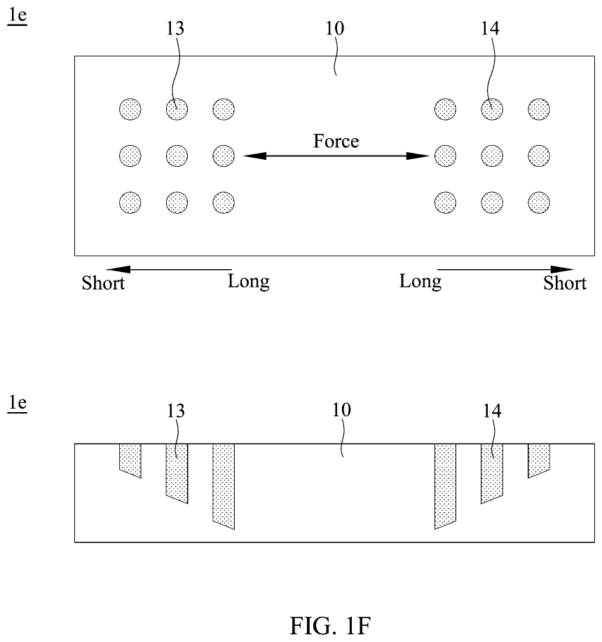

FIG. 1A illustrates a cross-sectional view of an electronic device la in accordance with some arrangements of the present disclosure. In some arrangements, the electronic device 1a may include a wearable device, such as a smartwatch, a smart band, or another smart wearable device.

In some arrangements, the electronic device la may be a piece of equipment that detects an external signal by using various detection devices (such as sensors). In some arrangements, the electronic device la may perform data communication with a base station or a terminal device (such as a mobile phone) in a wireless manner, such as via radio frequency identification or short-range wireless communication. In some arrangements, the electronic device la may be used in combination with a detection device (such as a sensor), an electronic device (such as a signal processing device) and/or other corresponding external devices for further processing of acquired signals.

Referring to FIG. 1A, the electronic device la may include a carrier 10, electronic components 11 and 12, and structures 13 and 14.

The carrier 10 may include a supporting layer for structurally supporting the electronic components 11 and 12. The carrier 10 may include a surface 101 and a surface 102 opposite to the surface 101. The electronic components 11 and 12 may be disposed over the surface 102 of the carrier 10.

In some arrangements, when the electronic device la is worn by a user, the surface 101 may configured to face or attach the user's skin, and the electronic components 11 and 12 may be spaced apart from the user's skin by the carrier 10. In some arrangements, the electronic device la may include one or more sensing elements (not illustrated) adjacent to the surface 101 of the carrier 10. In some other arrangements, one or more of the sensing elements may be entirely surrounded, embedded, or covered by the carrier 10. In some other arrangements, one or more of the sensing elements may be configured to contact the user's skin. The sensing elements may each include a conductive pad or a sensing pad. For example, the sensing elements may each include an electrode, a thermistor, a pressure sensor, a proximity sensor, a motion sensor, an acoustic sensor, a smell sensor, a particle sensor, a humidity sensor, an optical transmitter, an optical receiver, an optical transceiver, or a combination thereof.

In some arrangements, the sensing elements may each be configured to detect or collect one or more signals or pieces of information external to the electronic device 1a. For example, the sensing elements may each be configured to detect light, sound, temperature, air pressure, smell, particle, humidity, or other environmental variables. For example, when the electronic device la is worn by a user, the sensing elements may be configured to detect or collect one or more signals (e.g., biosignals) or pieces of information associated with the user.

In some arrangements, when the electronic device 1a is worn by a user, the surface 102 may face the user's skin, and the carrier 10 may be spaced apart from the user's skin by the electronic components 11 and 12.

The carrier 10 may include a flexible printed circuit board or a flexible substrate. In some arrangements, the carrier 10 may be configured to be adjustable. For example, when the electronic device la is worn by a user, the carrier 10 may flexibly adjust its shape to conform to a body part of the user. For example, by bending, twisting, stretching, and/or compressing the carrier 10, the electronic device la can adhere to and move with the user's body. For example, the carrier 10 may be stretched along the direction D1. The direction D1 may be substantially parallel with the surface 101 and/or the surface 102 of the carrier 10.

The carrier 10 may be soft and flexible enough to be worn comfortably for an extended time. In some arrangements, the carrier 10 may include a dielectric material. The dielectric material may include, for example, but is not limited to, phosphoric anhydride (PA), a polyimide (PI), a polybenzoxazole (PBO), Borophosphosilicate Glass (BPSG), Undoped Silicate Glass (USG), silicon oxide, silicon nitride, silicon oxynitride, any combination of two or more thereof, or the like. In some arrangements, the carrier 10 may include rubber, silicon, sponge, or other suitable materials such as an elastic material, a soft material, or a flexible material. In some arrangements, the carrier 10 may include a liquid silicone rubber (LSR).

In some arrangements, the carrier 10 may include an interconnection structure. The interconnection structure may include a redistribution layer (RDL), a circuit layer, a conductive pillar, conductive pad, conductive trace, a conductive via, a conductive wire, or other conductive elements. The interconnection structure may provide signal paths for the components (such as the electronic components 11 and 12) electrically connected with the carrier 10.

For example, the carrier 10 may include a conductive trace 10t and conductive pads 10p1 and 10p2 adjacent to the surface 102.

The conductive pad 10p1 may be disposed under or below the electronic component 11 and electrically connected with the electronic component 11 through an electrical contact 11e. The conductive pad 10p2 may be disposed under or below the electronic component 12 and electrically connected with the electronic component 12 through an electrical contact 12e.

In some arrangements, the conductive pads 10p1 and 10p2 may protrude from the surface 102 of the carrier 10. However, in some other arrangements, the conductive pads 10p1 and 10p2 may be substantially coplanar with the surface 102 of the carrier 10.

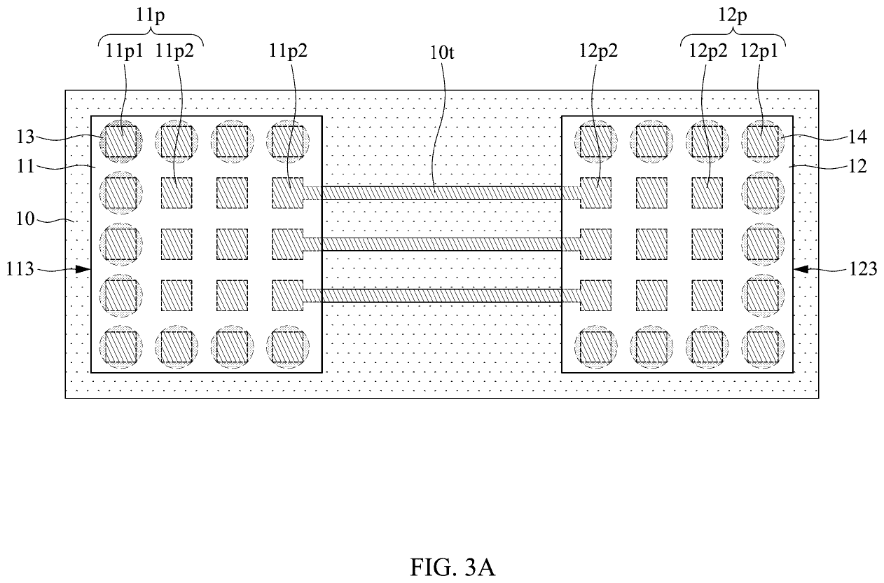

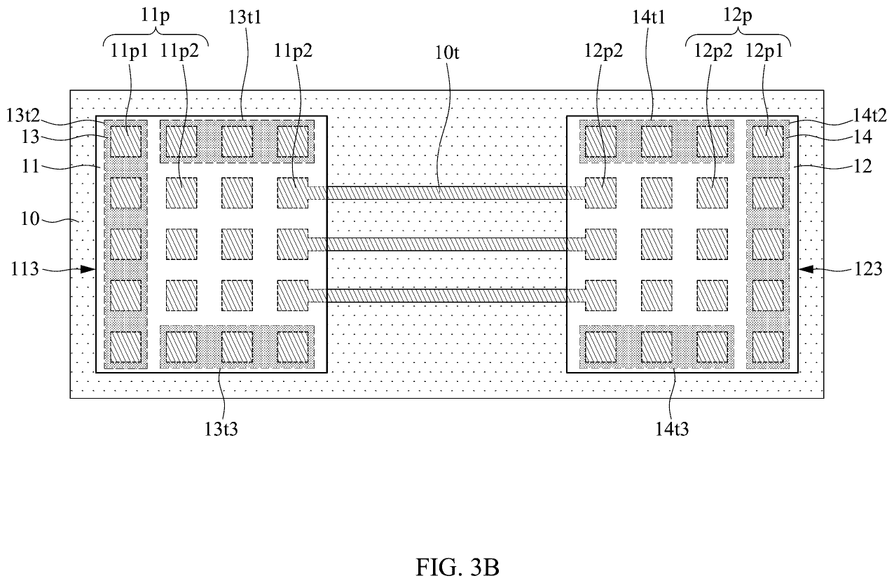

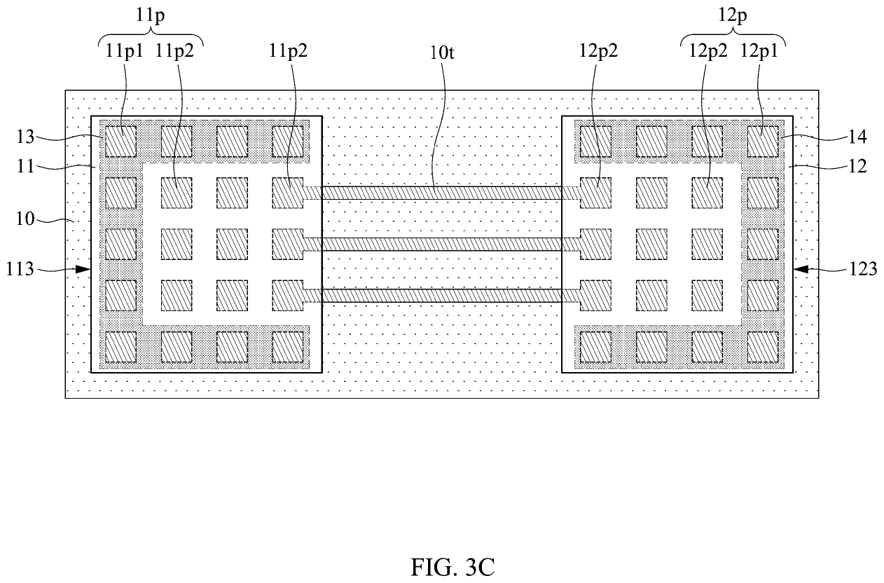

The conductive trace (or conductive element) 10t may extend between the electronic components 11 and 12. For example, as shown in FIG. 3A, the conductive trace 10t may extend from under the electronic component 11 to under the electronic component 12. The conductive trace 10t may be electrically connected with one or more of the conductive pads 10p1 and 10p2 as shown in FIG. 3A.

In some arrangements, the conductive trace 10t may be exposed from the surface 102 of the carrier 10. In some arrangements, the carrier 10 may include a protection layer covering the conductive trace 10t. In some arrangements, the protection layer may include a solder resist or a solder mask. In some arrangements, the conductive trace 10t may be substantially coplanar with the surface 102 of the carrier 10. For example, the conductive trace 10t may not protrude from the surface 102 of the carrier 10. However, in some other arrangements, the conductive trace 10t may protrude from the surface 102 of the carrier 10.

The carrier 10 be a monolithic layer or a monolithic carrier. However, the present disclosure is not limited thereto. For example, in some other arrangements, the carrier 10 may include a plurality of sublayers. The number of sublayers of the carrier 10 may be adjusted based on design requirements.

The electronic components 11 and 12 may be disposed over or on the surface 102 of the carrier 10. In some arrangements, the electronic components 11 and 12 may each be electrically connected to one or more other devices (if any) and to the carrier 10, and the electrical connection may be attained by way of flip-chip, wire-bond techniques, metal-to-metal bonding (such as Cu to Cu bonding), or hybrid bonding.

In some arrangements, the electronic components 11 and 12 may each include an active device or an active component. The electronic components 11 and 12 may each be or include circuits or circuit elements that rely on an external power supply to control or modify electrical signals. For example, the electronic components 11 and 12 may each be or include logic circuits. In some arrangements, the electronic components 11 and 12 may each include a passive device or a passive component, such as resistors, capacitors, inductors, or a combination thereof.

In some arrangements, the electronic components 11 and 12 may each include a processing device, a storage device, or a transmission device. For example, the electronic components 11 and 12 may each be configured to process (e.g., analyze, modify, synthesize, convert to a digital signal, and amplify, etc.), to store, and/or to transmit the signals (such as biosignals) detected by sensing elements (if any) in the electronic device la.

The positions, functions, and numbers of the electronic components in the electronic device la are not intended to limit the present disclosure. For example, there may be any number of electronic components in the electronic device la due to design requirements.

The electronic component 11 may include a surface 111, a surface 112 opposite to the surface 111, and a surface 103 extending between the surface 111 and the surface 112. A plurality of conductive pads (or conductive terminals) 11p may be disposed adjacent to or exposed at the surface 111. The conductive pads 11p may include a dummy pad, a ground pad, a signal pad, etc.

The dummy pad (or dummy terminal) is an unused pad for symmetry, alignment, or structural support. The dummy pad does not serve electrical connection function. The ground pad (or ground terminal) is a pad connected to ground for providing a reference point for electrical signals and reducing noise. The signal pad (or signal terminal) is used to make electrical connections and serves as an interface for transmitting or receiving electrical signals between the electronic components 11 and 12. In some arrangements, the dummy pad and/or the ground pad may provide electromagnetic shielding. For example, the dummy pad and/or the ground pad may reduce the level of electromagnetic interference (EMI) emanating from the signal pad or to protect the signal pad from EMI.

The surface 111 may face the carrier 10 and be electrically connected to the carrier 10 through the electrical contact 11e. In some arrangements, the electrical contact 11e may include solder balls or solder bumps, such as a controlled collapse chip connection (C4) bump, a ball grid array (BGA) or a land grid array (LGA). In some arrangements, the electrical contact 11e may include a pin, a joint, glue, and adhesive, etc. The electrical contact 11e may be disposed between the conductive pad 11p and the conductive pad 10p1. An underfill 11u may be provided in the gap between the surface 111 and the carrier 10. The underfill 11u may cover or surround the electrical contact 11e.

Similar to the electronic component 11, the electronic component 12 may include a surface 121, a surface 122 opposite to the surface 121, and a surface 123 extending between the surface 121 and the surface 122. A plurality of conductive pads (or conductive terminals) 12p may be disposed adjacent to or exposed at the surface 121. The conductive pads 12p may include a dummy pad, a ground pad, a signal pad, etc.

The surface 121 may face the carrier 10 and be electrically connected to the carrier 10 through the electrical contact 12e. The electrical contact 12e may include a solder ball, a solder bump, a pin, a joint, glue, and adhesive, etc. The electrical contact 12e may be disposed between the conductive pad 12p and the conductive pad 10p2. An underfill 12u may be provided in the gap between the surface 121 and the carrier 10. The underfill 12u may cover or surround the electrical contact 12e.

The carrier 10 may include recessed portions (or recessed regions) 10r which are recessed from the surface 102 of the carrier 10. The recessed portions 10r may be separated from one another.

A group of the recessed portions 10r may be under or below the electronic component 11, and a group of the recessed portions 10r may be under or below the electronic component 12. A group of the recessed portions 10r may be covered by the electronic component 11, and a group of the recessed portions 10r may be covered by the electronic component 12. A group of the recessed portions 10r may be overlapped with the electronic component 11, and a group of the recessed portions 10r may be overlapped with the electronic component 12. A group of the recessed portions 10r may be disposed on a side of the conductive trace 10t, and a group of the recessed portions 10r may be disposed on another side of the conductive trace 10t.

The structures 13 and 14 may be disposed in the recessed portions 10r. The recessed portions 10r may be filled with the structures 13 and 14. The structures 13 and 14 may each be at least partially surrounded, embedded, or covered by the carrier 10. In some other arrangements, one or more of the structures 13 and 14 may be entirely surrounded, embedded, or covered by the carrier 10.

The structures 13 may be under or below the electronic component 11. The structures 13 may be covered by the electronic component 11. The structures 13 may be overlapped with the electronic component 11 vertically (e.g., in a direction substantially perpendicular to the surface 101 and/or the surface 102 of the carrier 10).

The structures 13 may be spaced apart from the electronic component 11. The structures 13 may be separated from the electronic component 11. The structures 13 may not directly contact the electronic component 11.

The structures 13 may be disposed at an elevation different from the electronic component 11 with respect to the surface 101 and/or the surface 102 of the carrier 10. For example, the structures 13 may not be overlapped with the electronic component 11 horizontally (e.g., in a direction substantially parallel with the surface 101 and/or the surface 102 of the carrier 10).

The structures 13 may be connected between the carrier 10 and the electronic component 11. The structures 13 may be connected between the carrier 10 and the conductive pad 11p of the electronic component 11. In some arrangements, one or more of the structures 13 may be electrically connected between the carrier 10 and the electronic component 11. For example, one or more of the structures 13 may be electrically connected with a signal pad of the electronic component 11.

In some arrangements, one or more of the structures 13 may be electrically disconnected (or insulated) from the electronic component 11. For example, one or more of the structures 13 may be electrically connected with a dummy pad of the electronic component 11.

The structures 13 may be reinforcements. The structures 13 may be configured to secure the electronic component 11 to the carrier 10. In some arrangements, the structures 13 may be configured to reduce displacement between the carrier 10 and the electronic component 11. In some arrangements, the structures 13 may be configured to mitigate a stress from strain on the carrier 10. Strain on the carrier 10 may include a force tending to pull or stretch the carrier 10. In some arrangements, each of the structures 13 may be configured to individually distribute a stress between the carrier 10 and the electronic component 11.

The structures 14 may be under or below the electronic component 12. The structures 14 may have the same or similar configuration as the structures 13, and the detailed description of the structures 13 may also apply to the structures 14.

The structures 13 and 14 may each include a conductive material. The structures 13 and 14 may each include a soldering material, conductive material, or a reflowable material. In some arrangements, the structures 13 and 14 may each include copper (Cu), gallium (Ga), indium (In), tin (Sn), bismuth (Bi), or other suitable materials.

The bottom surface 13m of the structure 13 may be inclined with respect to the surface 101 and/or the surface 102 of the carrier 10. For example, the bottom surface 13m of the structure 13 may be non-parallel to the surface 101 and/or the surface 102 of the carrier 10. An imaginary extension line of the bottom surface 13m of the structure 13 may intersect the surface 101 and/or the surface 102 of the carrier 10. Similarly, the bottom surface 14m of the structure 14 may be inclined with respect to the surface 101 and/or the surface 102 of the carrier 10. For example, the bottom surface 14m of the structure 14 may be non-parallel to the surface 101 and/or the surface 102 of the carrier 10. An imaginary extension line of the bottom surface 14m of the structure 14 may intersect the surface 101 and/or the surface 102 of the carrier 10.

The structures 13 and 14 may each have different dimensions (such as depth or length) d1 and d2 in a vertical direction (e.g., in a direction substantially perpendicular to the surface 101 and/or the surface 102 of the carrier 10). The dimension d1 may be smaller than the dimension d2. For example, the dimension d2 may be deeper than the dimension d1 with respect to the surface 102 of the carrier 10.

For example, the sidewalls of a single or monolithic structure of the structures 13 and 14 may have different depths or lengths. In some arrangements, a single or monolithic structure of the structures 13 and 14 may have four sides from a cross-sectional view, and two of the sides may be parallel. For example, the sidewalls of a single or monolithic structure of the structures 13 and 14 may be parallel.

The bottom surfaces 13m of the structures 13 may tilt or be angled in the same direction as the bottom surfaces 14m of the structures 14. For example, the tilting direction of the bottom surfaces 13m and the tilting direction of the bottom surfaces 14m may be substantially the same with respect to the surface 101 and/or the surface 102 of the carrier 10. For example, the angle of the bottom surfaces 13m and the angle of the bottom surfaces 14m may be substantially the same with respect to the surface 101 and/or the surface 102 of the carrier 10.

In some arrangements, a width of a single or monolithic structure of the structures 13 and 14 may be greater than or exceed a depth of a single or monolithic structure of the structures 13 and 14. An aspect ratio of a single or monolithic structure of the structures 13 and 14 may be less than 1, such as about 0.5. For example, a single or monolithic structure of the structures 13 and 14 may have a dimension (such as thickness, width, and/or cross section) d3. In some arrangements, the dimension d3 may be greater than or equal to twice the dimension d2. In some arrangements, the dimension d3 may be greater than or equal to twice the dimension d1.

In some arrangements, a depth of a single or monolithic structure of the structures 13 and 14 may be greater than or exceed a width of a single or monolithic structure of the structures 13 and 14. An aspect ratio of a single or monolithic structure of the structures 13 and 14 may be greater than 1, such as about 2. In some arrangements, the dimension d2 may be greater than or equal to twice the dimension d3. In some arrangements, the dimension d1 may be greater than or equal to twice the dimension d3.

The carrier 10 may include regions 10A, 10B, and 10C. The regions 10A, 10B, and 10C may each be flexible, bendable, twistable, stretchable, and/or compressible. The regions 10A, 10B, and 10C may also be referred to as stretchable regions.

The electronic component 11 may be disposed over or on the region 10A and the electronic component 12 may be disposed over or on the region 10C. For example, the region 10A may support the electronic component 11. For example, the region 10C may support the electronic component 12. The structures 13 may be disposed in the region 10A and the structures 14 may be disposed in the region 10C. The region 10B may be disposed between the regions 10A and 10C. For example, the region 10B may not under the electronic component 11 or the electronic component 12. The region 10B may be connected between the regions 10A and 10C. The region 10B may be adjacent to the regions 10A and 10C.

In some arrangements, the structures 13 may constrain strain of the region 10A and the structures 14 may constrain strain of the region 10C.

In some arrangements, the region 10B may be relatively more flexible, bendable, twistable, stretchable, and/or compressible than the regions 10A and 10C. For example, when the carrier 10 is stretched along the direction D1, a dimension change (such as a length change) of the region 10B along the direction D1 may be greater than or exceed a dimension change (such as a length change) of the region 10A along the direction D1, and also greater than or exceed a dimension change (such as a length change) of the region 10C along the direction D1. For example, when a stress is applied to the carrier 10, strain of the region 10B may be greater than a strain of the region 10A, and also greater than or exceed strain of the region 10C.

In some arrangements, the regions 10A and 10C may be relatively more resistant to stress, impact, twisting or other physical or structural changes. In some arrangements, the relative positions of the regions 10A and 10C may be adjusted by changing the structure or the shape of the region 10B, such as by bending, twisting, stretching, compressing the region 10B. The region 10B may be configured to provide adjustment to a relative position between the regions 10A and 10C.

The electronic components 11 and 12 may be relatively more rigid than the carrier 10. For example, the Young's modulus of the electronic components 11 and 12 may be greater than or exceed 18 GPa, and the Young's modulus of the carrier 10 may be less than 0.5 GPa. The interface between two different materials (or between high modulus and low modulus materials) might deteriorate (delaminate, crack, or break) when the electronic device la is stretched or bent to conform to the user's body. Transmission problems may become severe, affecting detection quality and device reliability.

According to some arrangements of the present disclosure, the carrier 10 has the structures 13 and 14 to secure the electronic components 11 and 12 to the carrier 10, and enhance the structural strength between the electronic components 11 and 12 and the carrier 10. For example, when the carrier 10 is stretched along the direction D1, the structures 13 and 14 may be configured to mitigate, distribute, or absorb energy of tensile stress on the electronic components 11 and 12 from a strain of the carrier 10.

For example, the structures 13 and 14 may be configured to prevent the electronic components 11 and 12 from moving with respect to the carrier 10. For example, the structures 13 and 14 may be configured to prevent or reduce displacement between the carrier 10 and the electronic components 11 and 12.

For example, the electronic device la may be resilient, such that, after being stretched, it can return to its original state without deteriorating (such as cracking or breaking). Therefore, the electrical connections for the electronic components 11 and 12 are stable. The electronic components 11 and 12 can keep functioning while the carrier 10 is being stretched. Furthermore, when the electronic device la is worn by a user, the carrier 10 can flexibly adjust its shape to conform to a body part of the user.

FIG. 1B illustrates a cross-sectional view of an electronic device 1b in accordance with some arrangements of the present disclosure. The electronic device 1b in FIG. 1B is similar to the electronic device la in FIG. 1A except for the differences described as follows.

The tilting direction of the bottom surfaces 13m of the structures 13 under the electronic component 11 may be different from the tilting direction of the bottom surfaces 14m of the structures 14 under the electronic component 12.

For example, the structures 13 and 14 may each have different dimensions (such as depths or lengths) d1 and d2 in a direction (such as a vertical direction). The dimension near the edge of the carrier 10 is greater or deeper.

In some arrangements, the bottom surfaces 14m of the structures 14 may be disposed at different elevation with respect to the surface 102 of the carrier 10.

For example, the bottom surface 14m of the structure 14 near the edge of the carrier 10 may be disposed at a deeper elevation. For example, one of the bottom surfaces 14m of the structures 14 closer to an edge of the carrier 10 is disposed at a deeper elevation than another one of the bottom surfaces 14m of the structures 14 farther from the edge of the carrier 10.

According to some arrangements of the present disclosure, by using the structures having greater dimensions near the edge of the carrier 10, the structures may withstand a greater strain from the carrier 10.

For example, when the carrier 10 is stretched along the direction D1, the dimension d1 (which is greater than the dimension d2) may help increasing the structural support to withstand a greater strain from the carrier 10.

For example, when the carrier 10 is stretched along the direction D1, the structures 14 disposed at a deeper elevation may help increasing the structural support to withstand a greater strain from the carrier 10.

FIG. 1C illustrates a cross-sectional view of an electronic device 1c in accordance with some arrangements of the present disclosure. FIG. 1D illustrates a top view and a cross-sectional view of the electronic device 1c in accordance with some arrangements of the present disclosure. The electronic components 11 and 12 are not shown in FIG. 1D for conciseness. The electronic device 1c in FIGS. 1C and 1D is similar to the electronic device 1b in FIG. 1B except that the bottom surface 13m of the structure 13 near the edge of the carrier 10 may be disposed at a deeper elevation.

As shown in FIG. 1D, when the application point is at the edge of carrier 10 (e.g., stretching outward from the position of the electronic components 11 and 12 of FIG. 1C), such a design (e.g., the structure is long on the outside and short on the inside) allows the long structure to block most of the stress, and the short structure to block the residual stress in a gradual manner to prevent the delamination between the electronic components and the carrier 10. Since it is not necessary for all the structures to be long structures, the use of materials can be saved and the process can be simpler and faster.

FIG. 1E illustrates a conceptual view showing a state in which a user wears an electronic device le in accordance with some arrangements of the present disclosure. FIG. 1F illustrates a top view and a cross-sectional view of the electronic device le in accordance with some arrangements of the present disclosure. The electronic components 11 and 12 are not shown in FIG. 1F for conciseness. The electronic device le in FIG. 1E is similar to the electronic device 1c in FIG. 1C except for the differences described as follows.

The dimensions (such as depths or lengths) d1 and d2 in a direction (such as a vertical direction) of the structures 13 near the center of the carrier 10 is greater or deeper. The bottom surface 13m of the structure 13 near the center of the carrier 10 may be disposed at a deeper elevation. Similarly, the structures 14 have greater dimensions near the center of the carrier 10.

As shown in FIG. 1F, when the application point is at the center of carrier 10 (e.g., the electronic device 1e attaches to a joint of the user), such a design (e.g., the structure is long on the inside and short on the outside) allows the long structure to block most of the stress, and the short structure to block the residual stress in a gradual manner to prevent the delamination between the electronic components and the carrier 10. Since it is not necessary for all the structures to be long structures, the use of materials can be saved and the process can be simpler and faster.

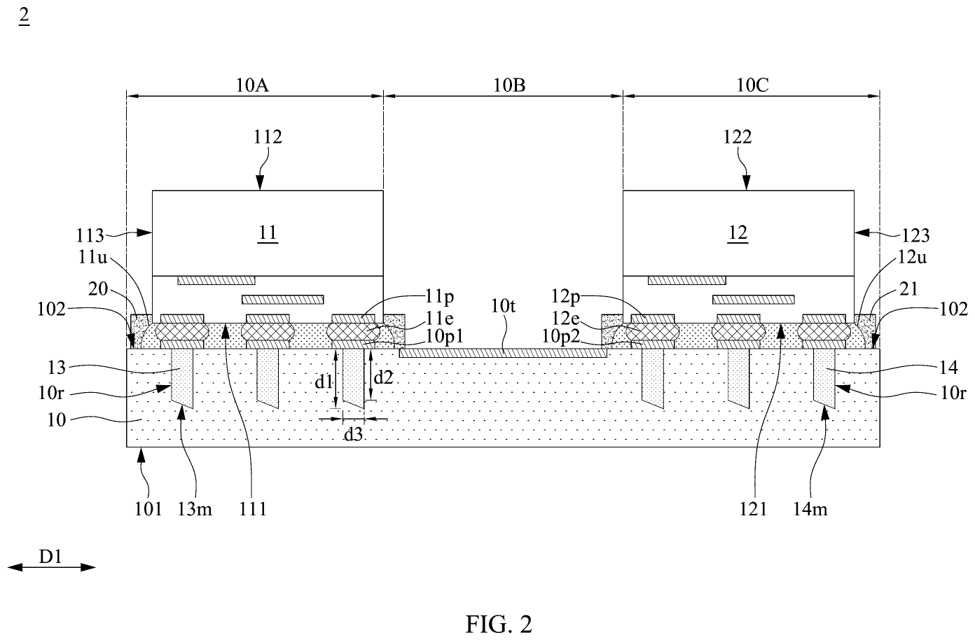

FIG. 2 illustrates a cross-sectional view of an electronic device 2 in accordance with some arrangements of the present disclosure. The electronic device 2 in FIG. 2 is similar to the electronic device la in FIG. 1A except for the differences described as follows.

In some arrangements, the electronic device 2 may include a buffer layer 20 between the electronic component 11 and the carrier 10. The buffer layer 20 may cover or surround a portion of the electronic component 11. The buffer layer 20 may cover or surround the underfill 11u.

In some arrangements, the electronic device 2 may include a buffer layer 21 between the electronic component 12 and the carrier 10. The buffer layer 21 may cover or surround a portion of the electronic component 12. The buffer layer 21 may cover or surround the underfill 12u.

In some arrangements, the buffer layers 20 and 21 may include adhesion promoting layers. In some arrangements, the buffer layers 20 and 21 may include a material of a Young's modulus between the Young's modulus of the carrier 10 and the Young's modulus of the electronic components 11 and 12. For example, the Young's modulus of the buffer layers 20 and 21 may be about 0.5 to 18 GPa. For example, the Young's modulus of the buffer layers 20 and 21 may be about 6 to 12 GPa.

In some arrangements, the buffer layers 20 and 21 may include a material of a coefficient of thermal expansion (CTE) between the CTE of the carrier 10 and the CTE of the electronic components 11 and 12.

The modulus of the buffer layers 20 and 21 may prevent sudden drops in modulus by providing a gradual transition between two materials with different moduli. The buffer layers 20 and 21 may help to distribute the stress more evenly and gradually transfer the load from one material to another, reducing the risk of sudden drops in modulus and potential failure.

In some arrangements, the buffer layers 20 and 21 may be configured to secure the electronic components 11 and 12 to the carrier 10, and to enhance the structural strength between the electronic components 11 and 12 and the carrier 10. In some arrangements, the buffer layers 20 and 21 may be configured to mitigate, distribute, or absorb energy of stress in a direction perpendicular to the direction D1. For example, the structures 13 and 14 may be configured facilitate horizontal stress distribution, and the buffer layers 20 and 21 may be configured facilitate vertical stress distribution.

FIG. 3A illustrates a top view of an electronic device in accordance with some arrangements of the present disclosure. The electronic device in FIG. 3A is similar to the electronic device la in FIG. 1A except for the differences described as follows.

Referring to FIG. 3A, as described above, the carrier 10 may include the conductive trace 10t. The electronic component 11 may include the conductive pads 11p. The conductive pads 11p may include a dummy pad, a ground pad, a signal pad, etc. The electronic component 12 may include the conductive pads 12p. The conductive pads 12p may include a dummy pad, a ground pad, a signal pad, etc.

Some of the conductive pads 11p may be overlapped with the structures 13. For example, the conductive pads 11p1 may each be overlapped with one of the structures 13, and the conductive pads 11p2 may not be overlapped with the structures 13. For example, the conductive pads 11p2 may be spaced apart from the structures 13.

Some of the conductive pads 12p may be overlapped with the structures 14. For example, the conductive pads 12p1 may each be overlapped with one of the structures 14, and the conductive pads 12p2 may not be overlapped with the structures 14. For example, the conductive pads 12p2 may be spaced apart from the structures 14.

In some arrangements, the conductive pads 11p1 and 12p1 may be the ground pads and/or the dummy pads. In some arrangements, the conductive pads 11p2 and 12p2 may be the signal pads.

In some arrangements, the conductive pads 11p1 and 12p1 may not be electrically connected with the conductive trace 10t. In some arrangements, the conductive pads 11p2 and 12p2 may be electrically connected with the conductive trace 10t.

In some arrangements, the ground pads and/or the dummy pads may be arranged at the outermost boundary of the conductive pads 11p. For example, the ground pads and/or the dummy pads may be arranged closer to the boundary (such as the surface 113) of the electronic component 11 than the signal pads. By arranging the ground pads and/or the dummy pads in the peripheral region of the electronic component 11 and the signal pads within the peripheral region, signal loss may be suppressed and signal paths for transmitting and receiving signals may be shortened. For example, as stated, the dummy pad and/or the ground pad may reduce the level of EMI emanating from the signal pad or to protect the signal pad from EMI.

The arrangements of the dummy pad, the ground pad, and the signal pad of the electronic component 12 may be similar to those of the electronic component 11, and the details are not repeated hereinafter.

The shapes, positions, relative locations, and numbers of the conductive pads 11p and 12p in FIGS. 3A-3C are for illustrative purposes only, and not intended to limit the present disclosure.

In some arrangements, the structures 13 may each be disposed under one of the ground pads and/or the dummy pads (such as the conductive pads 11p1) in the peripheral region of the electronic component 11. For example, the structures 13 may each overlap one of the ground pads and/or the dummy pads (such as the conductive pads 11p1) of the electronic component 11.

In some arrangements, the structures 14 may each be disposed under one of the ground pads and/or the dummy pads (such as the conductive pads 12p1) in the peripheral region of the electronic component 12. For example, the structures 14 may each overlap one of the ground pads and/or the dummy pads (such as the conductive pads 12p1) of the electronic component 12.

According to some arrangements of the present disclosure, by arranging the reinforcement (such as the structures 13 and 14) to connect the ground pad or dummy pad of the electronic component (such as the electronic components 11 and 12), the design flexibility of the electronic component may be enhanced without increasing the overall area thereof.

In addition, by arranging one of the reinforcements (such as one of the structures 13 and 14) to be under one of the conductive pads of the electronic component (such as the electronic components 11 and 12) in one-to-one correspondence, each of the reinforcements may be configured to individually distribute a stress between the carrier and the electronic component, which results in a more uniform stress distribution. In some arrangements, at least some of the reinforcements may be configured to individually distribute a stress between the carrier and the electronic component.

FIG. 3B illustrates a top view of an electronic device in accordance with some arrangements of the present disclosure. The electronic device in FIG. 3B is similar to the electronic device in FIG. 3A except for the differences described as follows.

The carrier 10 may include three recesses or trenches 13t1, 13t2, and 13t3. There may be three sections of structures 13 disposed within the trenches 13t1, 13t2, and 13t3. The structures 13 may extend below the conductive pads 11p1 and away from the conductive pads 11p1. The carrier 10 may include three recesses or trenches 14t1, 14t2, and 14t3. There may be three sections of structures 14 disposed within the trenches 14t1, 14t2, and 14t3. The structures 14 may extend below the conductive pads 12p1 and away from the conductive pads 12p1.

The sections of structures 13 may be aligned with the boundary (such as the surface 113) of the electronic component 11. The sections of structures 13 may be separated from one another. The sections of structures 13 may each be disposed under a plurality of the ground pads and/or the dummy pads (such as the conductive pads 11p1) in the peripheral region of the electronic component 11. For example, one of the sections of structures 13 may be disposed under three of the ground pads and/or the dummy pads (such as the conductive pads 11p1) in the peripheral region of the electronic component 11. For example, one of the sections of structures 13 may overlap three of the ground pads and/or the dummy pads (such as the conductive pads 11p1) of the electronic component 11.

The sections of structures 14 may be aligned with the boundary (such as the surface 123) of the electronic component 12. The sections of structures 14 may be separated from one another. The sections of structures 14 may each be disposed under a plurality of the ground pads and/or the dummy pads (such as the conductive pads 12p1) in the peripheral region of the electronic component 12. For example, one of the sections of structures 14 may be disposed under three of the ground pads and/or the dummy pads (such as the conductive pads 12p1) in the peripheral region of the electronic component 12. For example, one of the sections of structures 14 may overlap three of the ground pads and/or the dummy pads (such as the conductive pads 12p1) of the electronic component 12. The sections of structures 13 and structures 14 may include barriers, walls, or downward extensions at the edges of the f the electronic components 11 and 12.

FIG. 3C illustrates a top view of an electronic device in accordance with some arrangements of the present disclosure. The electronic device in FIG. 3C is similar to the electronic device in FIG. 3B except for the differences described as follows.

The structure 13 disposed between the electronic component 11 and the carrier 10 may be a monolithic structure. The structure 13 may aligned with the boundary (such as the surface 113) of the electronic component 11. The structure 13 may be disposed under a plurality of the ground pads and/or the dummy pads (such as the conductive pads 11p1) in the peripheral region of the electronic component 11.

The structure 14 disposed between the electronic component 12 and the carrier 10 may be a monolithic structure. The structure 14 may aligned with the boundary (such as the surface 123) of the electronic component 12. The structure 14 may be disposed under a plurality of the ground pads and/or the dummy pads (such as the conductive pads 12p1) in the peripheral region of the electronic component 12. The structures 13 and structures 14 may include barriers, walls, or downward extensions at the edges of the f the electronic components 11 and 12.

According to some arrangements of the present disclosure, by using sections of the reinforcement (such as the structures 13 and 14 in FIG. 3B) or monolithic reinforcement (such as the structures 13 and 14 in FIG. 3C) to connect a plurality of the ground pads or dummy pads of the electronic component (such as the electronic components 11 and 12), the reinforcement can be produced at a lower cost and with better productivity. In addition, the structures 13 and 14 in FIGS. 3B and 3C (which may be barriers, walls, or downward extensions at the edges of the f the electronic components 11 and 12) may be able to resist the forces and pressures exerted thereon and may withstand a greater strain from the carrier 10.

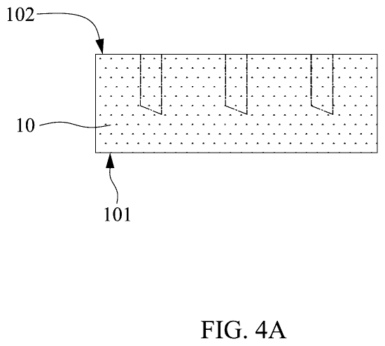

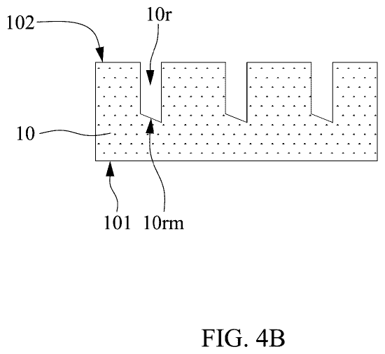

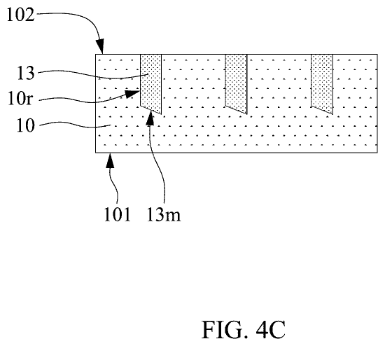

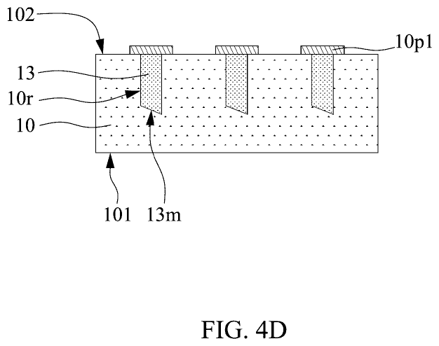

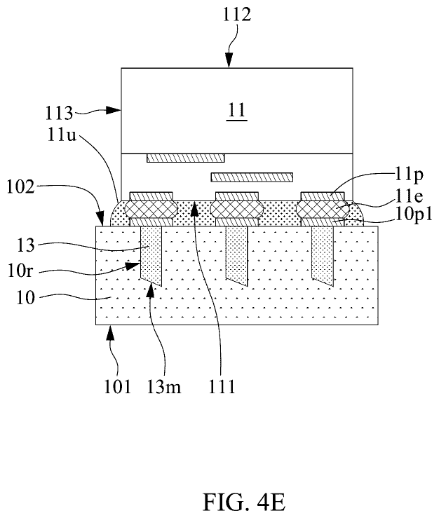

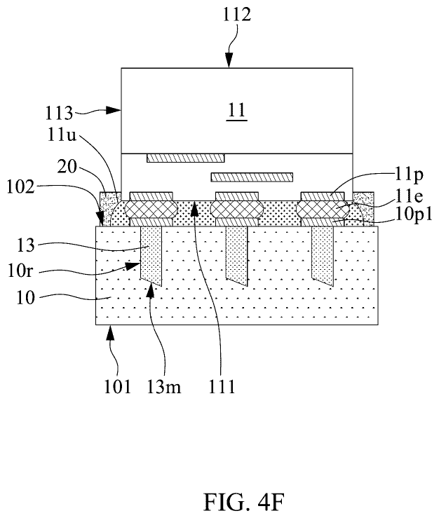

FIG. 4A, FIG. 4B, FIG. 4C, FIG. 4D, FIG. 4E, and FIG. 4F illustrate cross-sectional views in one or more stages of a method of manufacturing an electronic device in accordance with an arrangement of the present disclosure. At least some of these figures have been simplified to better understand the aspects of the present disclosure. In some arrangements, a part of the electronic device 2 may be manufactured through the operations described with respect to FIG. 4A, FIG. 4B, FIG. 4C, FIG. 4D, FIG. 4E, and FIG. 4F.

Referring to FIG. 4A, the carrier 10 may be provided. The carrier 10 may include the surface 101 and the surface 102 opposite to the surface 101. The locations of the recessed portions may be predetermined based on the locations of the electronic components (such as the electronic component 11 in FIG. 4E).

Referring to FIG. 4B, the recessed portions 10r may be formed by removing parts of the carrier 10 through, for example, laser cutting technology. The bottom surfaces 10rm of the recessed portions 10r may be inclined with respect to the surface 101 and/or the surface 102 of the carrier 10.

Referring to FIG. 4C, the material of the structures 13 may be disposed in the recessed portions 10r. The structures 13 may include a suitable soldering material, conductive material, or a reflowable material. The structures 13 may be formed by a printing operation, a transferring operation, a dispensing operation, a plating operation, or any other suitable method.

Referring to FIG. 4D, the interconnection structure may be formed or disposed on the carrier 10. The pattern or the routing of the interconnection structure may be predetermined based on the locations of the electronic components in the following operations. For example, the conductive trace (such as the conductive trace 10t in FIG. 2) and conductive pads 10p1 may be formed or disposed on the carrier 10.

The interconnection structure may include any suitable conductive material, such as copper, copper alloy, aluminum, silver, gold, a combination thereof, etc. The interconnection structure may be formed by any suitable technique, such as plating, sputtering, printing, chemical vapor deposition, etc.

Referring to FIG. 4E, the electronic component 11 may be disposed over or on the carrier 10 and electrically connected to the conductive pads 10p1 through the electrical contact 11e. Since the electronic component 12 undergoes to similar or identical processes in the manufacturing method, for convenience, only the electronic component 11 is illustrated and described in the following description.

An underfill 11u may be provided in the gap between the surface 111 and the carrier 10. The underfill 11u may cover or surround the electrical contact 11e.

Referring to FIG. 4F, the buffer layer 20 may be provided between the electronic component 11 and the carrier 10.

In some arrangements, a singulation may be performed to separate out individual electronic devices. The singulation may be performed, for example, by using a dicing saw, laser or other appropriate cutting techniques.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of arrangements of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 um, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific arrangements thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other arrangements of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic device, comprising:
a carrier configured to be stretchable;
a first electronic component disposed over the carrier; and
a structure at least partially disposed within the carrier and connected to the first electronic component,
wherein the structure is configured to reduce displacement between the carrier and the first electronic component.

2. The electronic device of claim 1, wherein the structure is disposed under the first electronic component.

3. The electronic device of claim 2, wherein the structure is disposed at a peripheral region of the first electronic component from a top view.

4. The electronic device of claim 1, wherein the structure is connected to the first electronic component through a conductive terminal.

5. The electronic device of claim 4, wherein the conductive terminal includes a ground terminal or a dummy terminal.

6. The electronic device of claim 1, wherein a depth of the structure in the carrier is greater than a width of the structure in a cross-sectional view.

7. The electronic device of claim 1, wherein the carrier includes a first stretchable region not under the first electronic component and a second stretchable region supporting the first electronic component, the structure is disposed in the second stretchable region to constrain a strain of the second stretchable region.

8. The electronic device of claim 7, further comprising:
a second electronic component disposed over the carrier, wherein the carrier includes a third stretchable region supporting the second electronic component, and the first stretchable region is disposed between the second stretchable region and the third stretchable region, wherein a strain of the third stretchable region is less than a strain of the first stretchable region when the carrier is stretched.

9. The electronic device of claim 8, wherein the carrier includes a conductive element in the first stretchable region and configured to electrically connect the first electronic component and the second electronic component.

10. The electronic device of claim 9, wherein the conductive element extends under the first electronic component and the second electronic component.

11. An electronic device, comprising:
a carrier configured to be stretchable;
a first electronic component disposed over the carrier; and
a first structure vertically extending in the carrier and connected to the first electronic component,
wherein the first structure is configured to mitigate a stress from a strain of the carrier.

12. The electronic device of claim 11, wherein a bottom surface of the first structure is inclined with respect to a surface of the carrier over which the first electronic component is disposed.

13. The electronic device of claim 11, wherein the first structure has different dimensions in a vertical direction.

14. The electronic device of claim 11, further comprising:
a second electronic component disposed over the carrier; and
a second structure vertically extending in the carrier and connected to the first electronic component,
wherein a tilting direction of a bottom surface of the first structure is different from a tilting direction of a bottom surface of the second structure.

15. The electronic device of claim 14, wherein the carrier includes a stretchable region between the first structure and the second structure, and configured to provide adjustment to a relative position between the first structure and the second structure.

16. An electronic device, comprising:
a carrier configured to be stretchable;
a first electronic component disposed over the carrier; and
a plurality of first structures disposed within the carrier and under the first electronic component,
wherein at least some of the plurality of first structures are configured to individually distribute a stress between the carrier and the first electronic component.

17. The electronic device of claim 16, wherein, in a cross-sectional view, bottom surfaces of the plurality of first structures are disposed at different elevations with respect to a surface of the carrier over which the first electronic component is disposed.

18. The electronic device of claim 16, wherein, in a cross-sectional view, a bottom surface of one of the plurality of first structures closer to a first edge of the carrier is disposed at a deeper elevation than a bottom surface of another one of the plurality of first structures farther from the first edge of the carrier.

19. The electronic device of claim 18, further comprising:
a second electronic component disposed over the carrier; and
a plurality of second structures disposed within the carrier and under the second electronic component,
wherein, in the cross-sectional view, bottom surfaces of the plurality of second structures are disposed at different elevations with respect to a surface of the carrier over which the second electronic component is disposed.

20. The electronic device of claim 19, wherein the carrier has a second edge opposite the first edge, a bottom surface of one of the plurality of second structures closer to the second edge of the carrier is disposed at a deeper elevation than a bottom surface of another one of the plurality of second structures farther from the second edge of the carrier.
